(19) United States
(12) Patent Application Publication
(10) Pub. No.: US 2012/0261770 A1
(43) Pub. Date: Oct. 18, 2012

(54) METAL GATE STRUCTURE

(76) Inventors: Kun-Hsien Lin, Tainan County (TW); Hsin-Fu Huang, Tainan City (TW); Tzung-Ying Lee, Ping-Tung County (TW); Min-Chuan Tsai, New Taipei City (TW); Chi-Mao Hsu, Tainan City (TW); Chin-Fu Lin, Tainan City (TW)

(21) Appl. No.: 13/086,397

(22) Filed: Apr. 14, 2011

(51) Int. Cl. H01L 29/772

(52) U.S. Cl. 257/410; 257/E29.242

(57) ABSTRACT

A metal gate structure includes a high-K gate dielectric layer, an N-containing layer, a work function metal layer, and an N-trapping layer. The N-containing layer is positioned between the work function metal layer and the high-K gate dielectric layer. The N-trapping layer is positioned between the work function metal layer and the high-K gate dielectric layer, and the N-trapping layer contains no nitrogen or low-concentration nitrogen.

### BACKGROUND OF THE INVENTION

1. Field of the Invention

The invention relates to a metal gate structure, and more particularly, to an n-type metal gate structure.

2. Description of the Prior Art

With a trend towards scaling down size of the semiconductor device, conventional methods, which are used to achieve optimization, such as reducing thickness of the gate dielectric layer, for example the thickness of silicon dioxide layer, have faced problems such as leakage current due to tunneling effect. In order to keep progression to next generation, high dielectric constant (high-K) materials are used to replace the conventional silicon oxide to be the gate dielectric layer because it decreases physical limit thickness effectively, reduces leakage current, and obtains equivalent capacitor in an identical equivalent oxide thickness (EOT).

On the other hand, the conventional polysilicon gate also has faced problems such as inferior performance due to boron penetration and unavoidable depletion effect which increases equivalent thickness of the gate dielectric layer, reduces gate capacitance, and worsens a driving force of the devices. Thus work function metals are developed to replace the conventional polysilicon gate to be the control electrode that competent to the high-K gate dielectric layer.

However, there is always a continuing need in the semiconductor processing art to develop semiconductor device renders superior performance and reliability even though the conventional silicon dioxide or silicon oxynitride gate dielectric layer is replaced by the high-K gate dielectric layer and the conventional polysilicon gate is replaced by the metal gate.

### SUMMARY OF THE INVENTION

According to an aspect of the present invention, there is provided a metal gate structure. The metal gate structure includes a high-K gate dielectric layer, a work function metal layer, a nitrogen-containing (N-containing) layer positioned between the work function metal layer and the high-K gate dielectric layer, and a nitrogen-trapping (N-trapping) layer positioned between the work function metal layer and the high-K gate dielectric layer. The N-trapping layer contains no nitrogen.

According to another aspect of the present invention, there is provided a metal gate structure. The metal gate structure includes a high-K gate dielectric layer, a work function metal layer, an N-containing layer positioned between the work function metal layer and the high-K gate dielectric layer, and an N-trapping layer positioned between the work function metal layer and the high-K gate dielectric layer. The N-trapping layer contains low-concentration nitrogen.

According to the metal gate structure provided by the present invention, the N-trapping layer is provided to trap nitrogen from the N-containing layer. Consequently metal diffusion from the work function metal layer is improved. After tuning work function metal, the N-trapping layer traps nitrogen from the N-containing layer and thus the N-trapping layer obtains low-concentration nitrogen. Accordingly, not only the metal diffusion from the work function metal layer is improved but also the work function of the metal gate is tuned to an ideal value: 3.9-4.3 eV. In other word, the present invention provides a metal gate structure having superior reliability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 are drawings illustrating a metal gate structure provided by a first preferred embodiment of the present invention.

FIG. 3 is a drawing illustrating a modification to the first preferred embodiment.

FIG. 4 is a drawing illustrating a metal gate structure provided by a second preferred embodiment of the present invention.

FIG. 5 is a drawing illustrating a modification to the second preferred embodiment.

FIG. 6 is a drawing illustrating another modification to the second preferred embodiment.

FIG. 7 is a drawing illustrating a metal gate structure provided by a third preferred embodiment of the present invention.

FIG. 8 is a drawing illustrating a modification to the third preferred embodiment.

### DETAILED DESCRIPTION

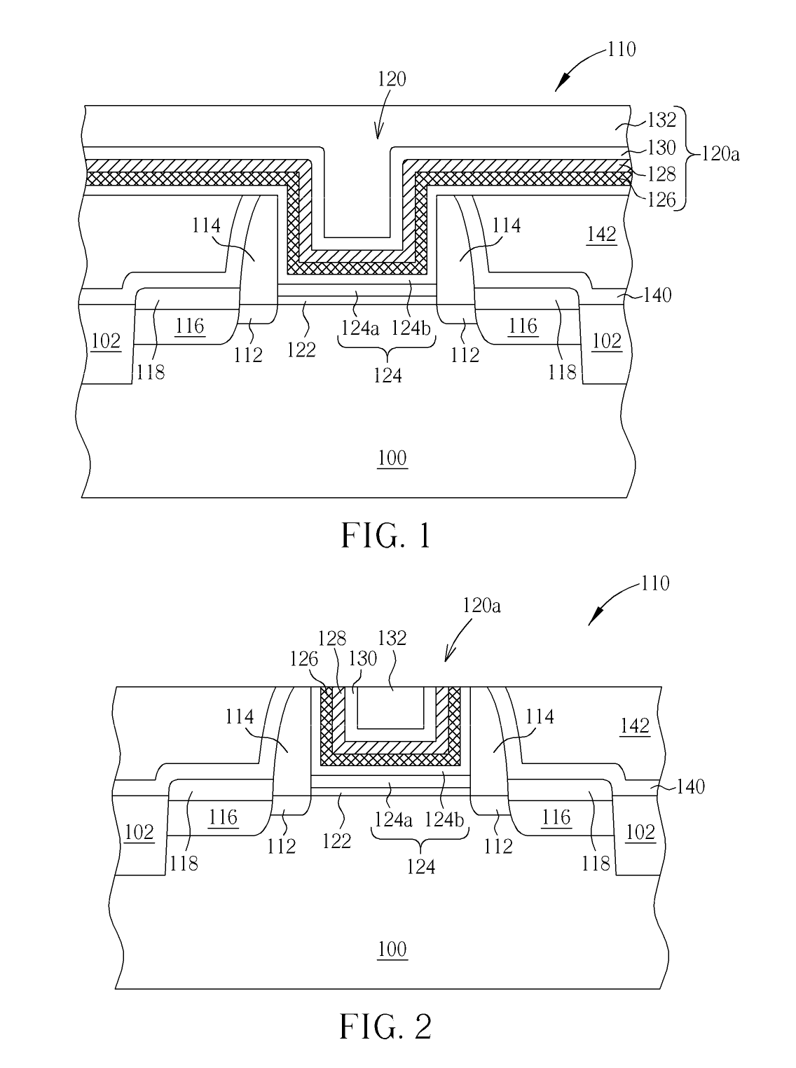

Please refer to FIGS. 1-2, which are drawings illustrating a metal gate structure provided by a first preferred embodiment of the present invention. It is noteworthy that the preferred embodiment is applied with the gate-last process. As shown in FIG. 1, a substrate 100 such as a silicon substrate, a silicon-containing substrate, or a silicon-on-insulator (SOI) substrate is provided, and a plurality of shallow trench isolations (STIs) 102 is formed in the substrate 100 for providing electrical isolation. Then, at least a semiconductor device 110 is formed on the substrate 100. The semiconductor device 110 includes a metal gate 120a formed in a gate trench 120 and lightly doped drains (LDDs) 112. Since the semiconductor device 110 provided by the preferred embodiment is an n-type semiconductor device, the LDDs 112 are accordingly n-type LDDs. The semiconductor device 110 also includes a spacer 114 formed on the sidewalls of metal gate 120a. The spacer 114 is preferably a multi-layered structure. The semiconductor device 110 further includes an n-type source/drain 116 and silicides 118 formed for reducing resistance. Additionally, selective epitaxial growth (SEG) method can be utilized to form the source/drain 116 in the preferred embodiment. As mentioned above, since the semiconductor device 110 is an n-type semiconductor device, epitaxial silicon layers having silicon carbide (SiC) can be used to form the n-type source/drain 116. Furthermore, a contact etch stop layer (CESL) 140 and an inter-layer dielectric (ILD) layer 142 are sequentially formed on the semiconductor device 110 and the substrate 100. Since steps for forming the metal gate 120a, the LDDs 112, the spacer 114, the source/drain 116, the silicides 118, the CESL 140 and the ILD layer 142 are well-known to those skilled in the art, those details are omitted herein in the interests of brevity.

Please still refer to FIG. 1. According to the first preferred embodiment, the metal gate 120a includes a gate dielectric layer 122, an N-containing layer 124, an N-trapping layer 126, a work function metal layer 128, a top barrier layer 130, and a low-resistance metal layer 132 sequentially and upwardly stacked in the gate trench 120 with the low-resistance metal layer 132 filling in the gate trench 120. The low-resistance metal layer 132 can include aluminum (Al), but not limited to this. The top barrier layer 130 can include a titanium nitride (TiN) layer or titanium oxynitride (TiON) layer, however the top barrier layer 130 can include any proper material capable of preventing the low-resistance metal layer 132 from reacting with the metal layer under the top barrier layer 130. The work function metal layer 128 includes a TiN single-layered structure, a titanium tri-aluminide (TiAl₃) single-layered structure, or a Ti/AI bi-layered structure. The N-containing layer 124 includes TiN, tantalum nitride (TaN), or their combination, and preferably includes a bi-layered structure having a TiN layer 124a and a TaN layer 124b. The TiN layer 124a of the N-containing layer 124 serves as a bottom barrier layer and the TaN layer 124b serves as an etch stop layer. Furthermore, the metal gate 120a also includes an interfacial layer (not shown) formed prior to the gate dielectric layer 122.

As mentioned above, the preferred embodiment is applied with the high-K first process, therefore the gate dielectric layer 122 includes a high-K gate dielectric layer 122 which includes materials selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), and hafnium zirconium oxide (HfZrO₄).

It is noteworthy that the preferred embodiment provides the N-trapping layer 126 positioned between the N-containing layer 124 and the work function metal layer 128, and a thickness of the N-trapping layer 126 is between 10 angstroms (Å) and 70 Å. The N-trapping layer 126 contains no nitrogen. The N-trapping layer 126 includes materials selected from the group consisting of titanium (Ti), tantalum (Ta), lanthanum (La), yttrium (Y), hafnium (Hf), niobium (Nb), zirconium (Zr) and vanadium (V). It is well-known to those skilled in the art that when tuning work function of the metal gate structure, Al is diffused from the work function metal layer 128 and toward the high-K gate dielectric layer 122. Therefore, the N-trapping layer 126 is provided to trap nitrogen from the N-containing layer 124 for reducing barrier function of the N-containing layer 124 and for improving Al diffusion rate and Al diffusion result.

Please refer to FIG. 2. Accordingly, the N-trapping layer 126 contains low-concentration nitrogen trapped from the N-containing layer 124 after tuning the work function of the metal gate 120a. Thereafter, a planarization process such as a chemical mechanical polishing (CMP) process is performed to remove the unnecessary low-resistance metal layer 132, top barrier layer 130, work function metal layer 128, N-trapping layer 126, and TaN layer 124b to obtain the metal gate 120a having ideal work function. As shown in FIG. 2, cross-sectional views of the TaN layer 124b, the N-trapping layer 126, the work function metal layer 128, and the top barrier layer 130 respectively include a U shape.

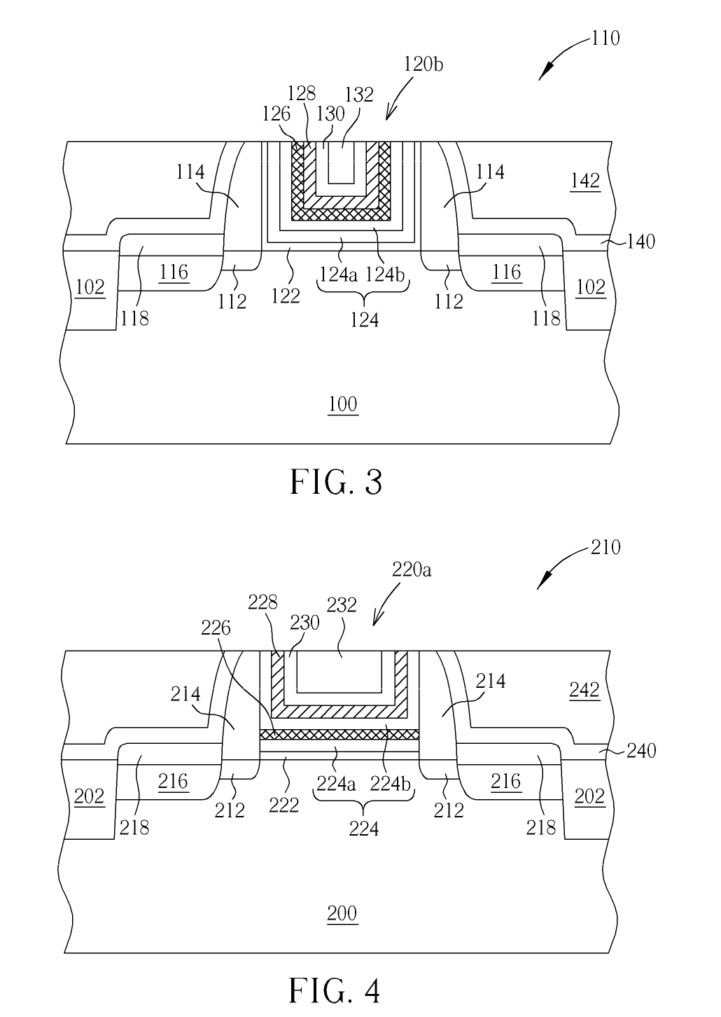

Please refer to FIG. 3, which is a drawing illustrating a modification to the first preferred embodiment. According to the modification, the metal gate 120b is provided by applying the high-K last process. Nevertheless, the N-trapping layer 126 is stilled positioned between the work function metal layer 128 and the N-containing layer 124. In detail, the substrate 100 or the interfacial layer (not shown) is exposed in the bottom of the gate trench 120 after forming the gate trench 120. Then, the high-K gate dielectric layer 122, the N-containing layer 124, the N-trapping layer 126, the work function metal layer 128, the top barrier layer 130, and the low-resistance metal layer 132 are sequentially formed in the gate trench 120. Accordingly, after removing the unnecessary layers by the CMP process, cross-sectional views of the high-K gate dielectric layer 122, the N-containing layer 124, the N-trapping layer 126, the work function metal layer 128, and the top barrier layer 130 of the metal gate 120b respectively include a U shape as shown in FIG. 3.

According to the first preferred embodiment, the N-trapping layer 126 containing no nitrogen is positioned between the work function metal layer 128 and the N-containing layer 124 of the metal gate 120a/120b. And the N-trapping layer 126 traps nitrogen from the N-containing layer 124, therefore the barrier function of the N-containing layer 124 is reduced while Al diffusion rate and diffusion result of the work function metal layer 128 is improved. Consequently, after tuning the work function of the metal gate 120a/120b, the N-trapping layer 126 of the metal gate 120a/120b contains low concentration nitrogen from the N-containing layer 124 while the metal diffusion of the work function metal layer 128 is improved. Accordingly, the work function of the metal gate 120a/120b is provided with the ideal value: 3.9˜4.3 eV.

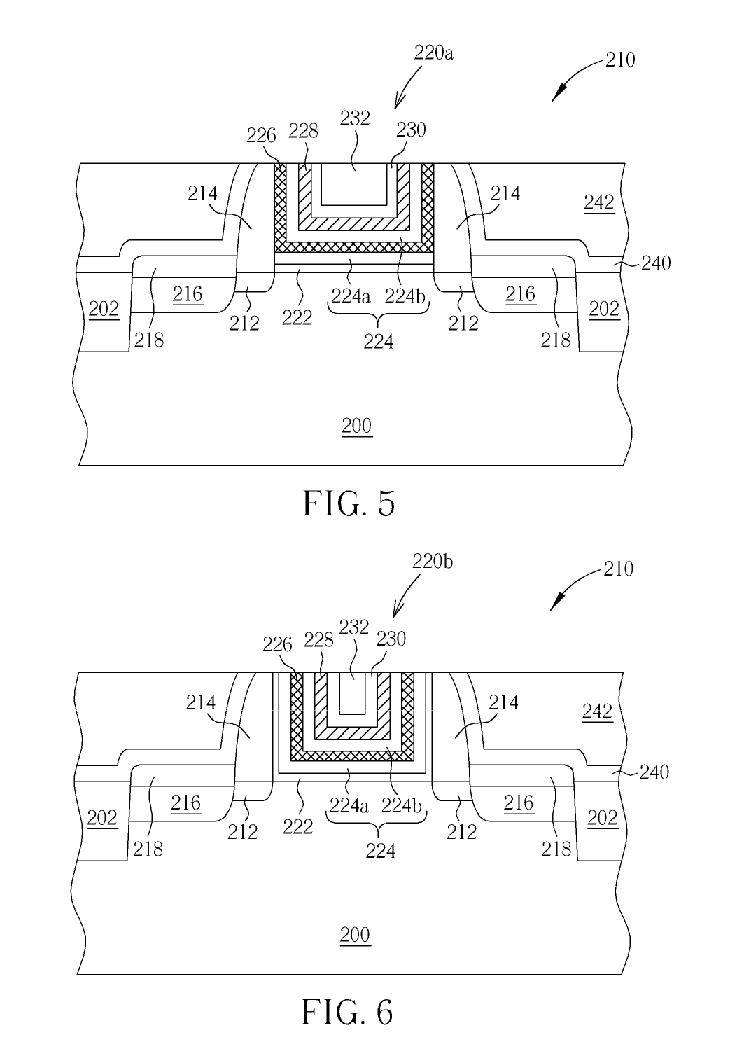

Please refer to FIG. 4 and FIG. 5, which respectively are a drawing illustrating a metal gate structure provided by a second preferred embodiment of the present invention and a drawing illustrating a modification to the second preferred embodiment. It is noteworthy that the second preferred embodiment is also applied with the gate-last process. Additionally, material choices for elements the same in both of the first and second preferred embodiment are omitted herein in the interest of brevity. As shown in FIG. 4, a substrate 200 having a plurality of STIs 202 for providing electrical isolation is first provided. Then, at least a semiconductor device 210 is formed on the substrate 200. The semiconductor device 210 includes a metal gate 220a and LDDs 212. Since the semiconductor device 210 provided by the preferred embodiment is also an n-type semiconductor device, the LDDs 212 are accordingly n-type LDDs. The semiconductor device 210 also includes a spacer 214 formed on the sidewalls of metal gate 220a, and the spacer 214 is preferably a multi-layered structure. The semiconductor device 210 further includes an n-type source/drain 216 and silicides 218 formed for reducing resistance. Additionally, the SEG method can be utilized to form the source/drain 216 in the preferred embodiment. Furthermore, a CESL 240 and an ILD layer 242 are sequentially formed on the semiconductor device 210 and the substrate 200.

Please still refer to FIG. 4. The preferred embodiment is further applied with the high-K first process. Accordingly, the metal gate 220a includes a gate dielectric layer 222, an N-containing layer 224, an N-trapping layer 226, a work function metal layer 228, a top barrier layer 230, and a low-resistance metal layer 232 sequentially and upwardly stacked in a gate trench (not shown) of the metal gate 220a with the low-resistance metal layer 232 filling in the gate trench. It is noteworthy that the N-containing layer 224 provided by the preferred embodiment is a bi-layered structure having a TiN layer 224a and a TaN layer 224b. The TiN layer 224a of the N-containing layer 224 serves as a bottom barrier layer and the TaN layer 224b serves as an etch stop layer. More important, the N-trapping layer 226 is sandwiched in between the bi-layered structured, that is, the N-trapping layer 226 is sandwiched in between the TiN layer 224a and the TaN layer 224b. Furthermore, the metal gate 220a also includes an interfacial layer (not shown) formed prior to the gate dielectric layer 222.

It is noteworthy that the preferred embodiment provides the N-trapping layer 226 sandwiched in between the bi-layered N-containing layer 224, and a thickness of the N-trapping layer 226 is between 10 Å and 70 Å. The N-trapping layer 226 contains no nitrogen. The N-trapping layer 226 includes materials selected from the group consisting of Ti, Ta, La, Y, Hf, Nb, Zr and V. When tuning work function of the metal gate structure, Al is diffused from the work function metal layer 228 and toward the gate dielectric layer 222. Therefore, the N-trapping layer 226 is provided to trap nitrogen, even to trap oxygen or carbon from its upper and lower N-containing layer 224 for reducing barrier function of the N-containing layer 224 and for improving Al diffusion rate and Al diffusion result. Furthermore, the N-trapping layer 226 is provided to cause conduction band edge shift, which lowers Fermi level. Consequently, electrical performance of an nMOS transistor is improved.

Please still refer to FIG. 4. Accordingly, the N-trapping layer 226 contains low-concentration nitrogen trapped from the N-containing layer 224 after tuning the work function of the metal gate 220a. Thereafter, a planarization process such as a CMP process is performed to remove unnecessary low-resistance metal layer 232, top barrier layer 230, work function metal layer 228, and TaN layer 224b to obtain the metal gate 220a having ideal work function as shown in FIG. 4. And cross-sectional views of the TaN layer 224b, the work function metal layer 228, and the top barrier layer 230 of the metal gate 220a respectively include a U shape as shown in FIG. 4. Additionally, please refer to FIG. 5 which illustrating a modification to the second preferred embodiment. According to the modification, the N-trapping layer 226, the TaN layer 224b, the work function metal layer 228, and the top barrier layer 230 of the metal gate 220a respectively include a U shape as shown in FIG. 5.

Please refer to FIG. 6, which is a drawing illustrating another modification to the second preferred embodiment. According to the modification, the metal gate 220b is provided by applying the high-K last process. Nevertheless, the N-trapping layer 226 is stilled sandwiched in between the bi-layered N-containing layer 224. In detail, the substrate 200 or the interfacial layer (not shown) is exposed in the bottom of the gate trench after forming the gate trench. Then, the high-K gate dielectric layer 222, the TiN layer 224a of the N-containing layer 224, the N-trapping layer 226, the TaN layer 224b of the N-containing layer 224, the work function metal layer 228, the top barrier layer 230, and the low-resistance metal layer 232 are sequentially formed in the gate trench. Accordingly, after removing the unnecessary layers by the CMP process, cross-sectional views of the high-K gate dielectric layer 222, the N-containing layer 224 (including the TiN layer 224a and the TaN layer 224b), the N-trapping layer 226, the work function metal layer 228, and the top barrier layer 230 of the metal gate 220b respectively include a U shape as shown in FIG. 6.

According to the second preferred embodiment, the N-trapping layer 226 containing no nitrogen is positioned in between the bi-layered N-containing layer 224, that is positioned between the TiN layer 224a and the TaN layer 224b. And the N-trapping layer 226 traps nitrogen, oxygen and carbon from its upper and lower N-containing layer 224, therefore the barrier function of the N-containing layer 224 is reduced, Al diffusion rate and diffusion result of the work function metal layer 228 is improved. Consequently, after tuning the work function of the metal gate 220a/220b, the N-trapping layer 226 contains low concentration nitrogen from the N-containing layer 224 while the metal diffusion of the work function metal layer 228 is improved. Accordingly, the work function of the metal gate 220a/220b is tuned to the ideal value: 3.9˜4.3 eV.

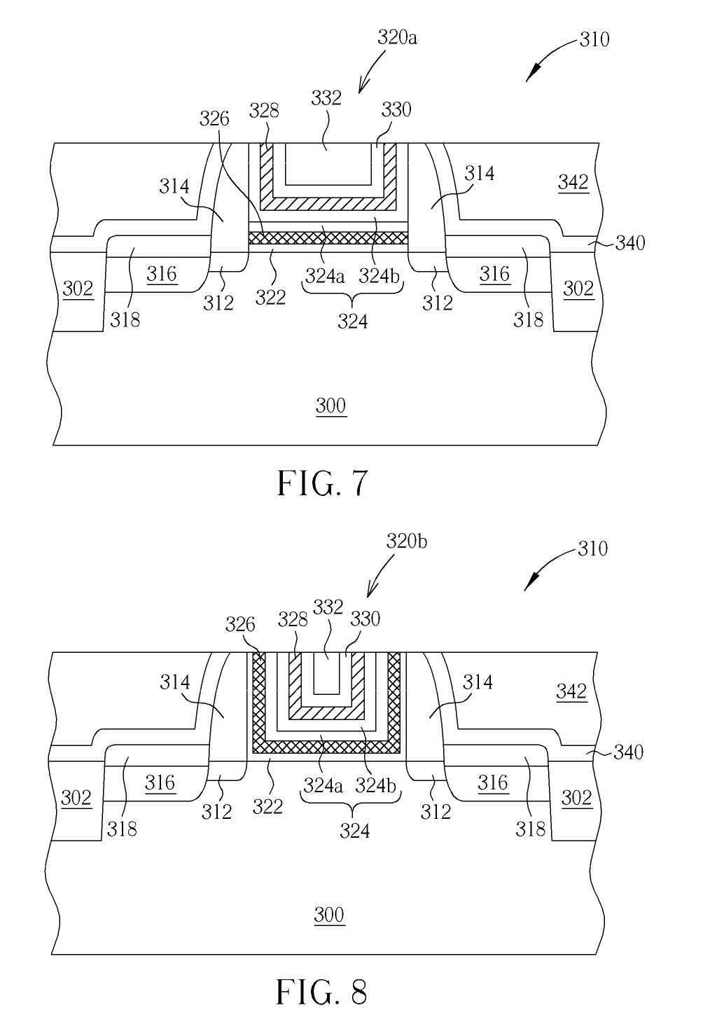

Please refer to FIG. 7 and FIG. 8, which respectively are a drawing illustrating a metal gate structure provided by a third preferred embodiment of the present invention and a drawing illustrating a modification to the third preferred embodiment. It is noteworthy that the second preferred embodiment is also applied with the gate-last process. Additionally, material choices for elements the same in both of the first, second and third preferred embodiment are omitted herein in the interest of brevity. As shown in FIG. 4, a substrate 300 having a plurality of STIs 302 for providing electrical isolation is first provided. Then, at least a semiconductor device 310 is formed on the substrate 300. The semiconductor device 310 includes a metal gate 320a and LDDs 312. Since the semiconductor device 310 provided by the preferred embodiment is also an n-type semiconductor device, the LDDs 312 are accordingly n-type LDDs. The semiconductor device 310 also includes a spacer 314 formed on the sidewalls of metal gate 320a, and the spacer 314 is preferably a multi-layered structure. The semiconductor device 310 further includes an n-type source/drain 316 and silicides 318 formed for reducing resistance. Additionally, the SEG method can be utilized to form the source/drain 316 in the preferred embodiment. Furthermore, a CESL 340 and an ILD layer 342 are sequentially formed on the semiconductor device 310 and the substrate 300.

Please still refer to FIG. 7. The preferred embodiment is further applied with the high-K first process. Accordingly, the metal gate 320a includes a gate dielectric layer 322, an N-trapping layer 326, an N-containing layer 324, a work function metal layer 328, a top barrier layer 330, and a low-resistance metal layer 332 sequentially and upwardly stacked in a gate trench (not shown) of the metal gate 320a with the low-resistance metal layer 332 filling in the gate trench. The N-containing layer 324 includes TiN, TaN, or their combination, and preferably includes a bi-layered structure having a TiN layer 324a and a TaN layer 324b, but not limited to this. As mentioned above, the TiN layer 324a of the N-containing layer 324 serves as a bottom barrier layer and the TaN layer 324b of the N-containing layer 324 serves as an etch stop layer. Furthermore, the metal gate 320a also includes an interfacial layer (not shown) formed prior to the gate dielectric layer 322.

It is noteworthy that the preferred embodiment provides the N-trapping layer 326 positioned between the high-K gate dielectric layer 322 and the N-containing layer 324, and a thickness of the N-trapping layer 326 is between 10 Å and 70 Å. The N-trapping layer 326 contains no nitrogen. The N-trapping layer 326 includes materials selected from the group consisting of Ti, Ta, La, Y, Hf, Nb, Zr and V. When tuning work function of the metal gate structure, Al is diffused from the work function metal layer 328 and toward the gate dielectric layer 322. Therefore, the N-trapping layer 326 is provided to trap nitrogen from its upper N-containing layer 324 for reducing barrier function of the N-containing layer 324 and improving Al diffusion rate and Al diffusion result.

Please still refer to FIG. 7. Accordingly, the N-trapping layer 326 contains low-concentration nitrogen trapped from the N-containing layer 324 after tuning the work function of the metal gate 320a. Thereafter, a planarization process such as a CMP process is performed to remove the unnecessary low-resistance metal layer 332, top barrier layer 330, work function metal layer 328, and TaN layer 324b to obtain a metal gate 320a having ideal work function. As shown in FIG. 6, cross-sectional views of the TaN layer 324b, the work function metal layer 328, and the top barrier layer 330 of the metal gate 320a respectively include a U shape.

Please refer to FIG. 8, which is a drawing illustrating a modification to the third preferred embodiment. According to the modification, the metal gate 320b is provided by applying the high-K last process. Nevertheless, the N-trapping layer 326 is stilled positioned between the high-K gate dielectric layer 322 and the N-containing layer 324. In detail, the substrate 300 or the interfacial layer (not shown) is exposed in the bottom of the gate trench after forming the gate trench. Then, the high-K gate dielectric layer 322, the N-trapping layer 326, the N-containing layer 324, the work function metal layer 328, the top barrier layer 330, and the low-resistance metal layer 332 are sequentially formed in the gate trench. Accordingly, after removing the unnecessary layers by the CMP process, cross-sectional views of the high-K gate dielectric layer 322, the N-trapping layer 326, the N-containing layer 324 (including the TiN layer 324a and the TaN layer 324b), the work function metal layer 328, and the top barrier layer 330 of the metal gate 320b respectively include a U shape as shown in FIG. 8.

According to the third preferred embodiment, the N-trapping layer 326 containing no nitrogen is positioned between the N-containing layer 324 and the high-K gate dielectric layer 322. And the N-trapping layer 326 traps nitrogen from the N-containing layer 324, therefore the barrier function of the N-containing layer 324 is reduced, Al diffusion rate and diffusion result of the work function metal layer 328 is improved. Consequently, after tuning the work function of the metal gate 320a/320b, the N-trapping layer 326 contains low concentration nitrogen from the N-containing layer 324 while the metal diffusion of the work function metal layer 328 is improved. Accordingly, the work function of the metal gate 320a/320b is tuned to the ideal value: 3.9˜4.3 eV.

According to the metal gate structure provided by the present invention, the N-trapping layer positioned between the work function metal layer and the high-K gate dielectric layer is provided to trap nitrogen from the N-containing layer. Consequently, the barrier function of the N-containing layer is reduced and the metal diffusion from the work function metal layer is improved. After tuning work function metal, the N-trapping layer traps nitrogen from the N-containing layer, and thus the N-trapping layer obtains low-concentration nitrogen. Accordingly, metal diffusion from the work function metal layer is improved and the work function of the metal gate is tuned to an ideal value: 3.9-4.3 eV. In other word, the present invention provides a metal gate structure having superior reliability.

Those skilled in the art will readily observe that numerous modifications and alterations of the device and method may be made while retaining the teachings of the invention.

What is claimed is:

1. A metal gate structure comprising:
a high-K gate dielectric layer;
a work function metal layer;
a nitrogen-containing (N-containing) layer positioned between the work function metal layer and the high-K gate dielectric layer; and
a nitrogen-trapping (N-trapping) layer positioned between the work function metal layer and the high-K gate dielectric layer, wherein the N-trapping layer contains no nitrogen.

2. The metal gate structure according to claim 1, wherein the N-trapping layer comprises materials selected from the group consisting of titanium (Ti), tantalum (Ta), lanthanum (La), yttrium (Y), hafnium (Hf), niobium (Nb), zirconium (Zr) and vanadium (V).

3. The metal gate structure according to claim 1, wherein the N-trapping layer is positioned between the work function metal layer and the N-containing layer, and cross-sectional views of the N-trapping layer and the work function metal layer comprise a U shape.

4. The metal gate structure according to claim 1, wherein the N-trapping layer is positioned between the work function metal layer and the N-containing layer, and cross-sectional view of the high-K gate dielectric layer, the N-containing layer, the N-trapping layer, and the work function metal layer comprise a U shape.

5. The metal gate structure according to claim 1, wherein the N-containing layer comprises titanium nitride (TiN), tantalum nitride (TaN), or their combination.

6. The metal gate structure according to claim 5, wherein the N-containing layer is a bi-layered structure.

7. The metal gate structure according to claim 6, wherein the N-trapping layer is sandwiched in between the bi-layered structure, and a cross-sectional view of the work function metal layer comprises a U shape.

8. The metal gate structure according to claim 6, wherein the N-trapping layer is sandwiched in between the bi-layered structure, and cross-sectional view of the high-K gate dielectric layer, the N-containing layer, the N-trapping layer, and the work function metal layer comprise a U shape.

9. The metal gate structure according to claim 1, wherein the N-trapping layer is positioned between the N-containing layer and the high-K gate dielectric layer, and a cross-sectional view of the work function metal layer comprises a U shape.

10. The metal gate structure according to claim 1, wherein the N-trapping layer is positioned between the N-containing layer and the high-K gate dielectric layer, and cross-sectional views of the high-K gate dielectric layer, the N-trapping layer, the N-containing layer, and the work function metal layer comprise a U shape.

11. The metal gate structure according to claim 1, wherein the work function metal layer comprises a TiN single-layered structure, a titanium tri-aluminide (TiAl₃) single-layered structure, or a Ti/AI bi-layered structure.

12. The metal gate structure according to claim 1, further comprising a top barrier layer and a low-resistance metal layer sequentially formed on the work function metal layer.

13. A metal gate structure comprising:
a high-K gate dielectric layer;
a work function metal layer;
an N-containing layer positioned between the work function metal layer and the high-K gate dielectric layer; and
an N-trapping layer positioned between the work function metal layer and the high-K gate dielectric layer, wherein the N-trapping layer contains low-concentration nitrogen.

14. The metal gates structure of claim 13, wherein the N-trapping layer comprises materials selected from the group consisting of Ti, Ta, La, Y, Hf, Nb, Zr and V.

15. The metal gates structure of claim 13, wherein the N-trapping layer is positioned between the work function metal layer and the N-containing layer, and cross-sectional views of the N-trapping layer and the work function metal layer comprise a U shape.

16. The metal gates structure of claim 13, wherein the N-trapping layer is positioned between the work function metal layer and the N-containing layer, and cross-sectional views of the high-K gate dielectric layer, the N-containing layer, the N-trapping layer, the work function metal layer comprise a U shape.

17. The metal gates structure of claim 13, wherein the N-containing layer comprises TiN, TaN or their combination.

18. The metal gates structure of claim 17, wherein the N-containing layer is a bi-layered structure.

19. The metal gates structure of claim 18, wherein the N-trapping layer is sandwiched between the bi-layered structure, and a cross-sectional view of the work function metal layer comprises a U shape.

20. The metal gates structure of claim 18, wherein the N-trapping layer is sandwiched between the bi-layered structure, and cross-sectional views of the high-K gate dielectric layer, the N-containing layer, the N-trapping layer, and the work function metal layer comprise a U shape.

21. The metal gates structure of claim 13, wherein the N-trapping layer is positioned between the N-containing layer and the high-K gate dielectric layer, and a cross-sectional view of the work function metal layer comprises a U shape.

22. The metal gates structure of claim 13, wherein the N-trapping layer is positioned between the N-containing layer and the high-K gate dielectric layer, and cross-sectional views of the high-K gate dielectric layer, the N-trapping layer, the N-containing layer, and the work function metal layer comprise a U shape.

23. The metal gates structure of claim 13, wherein the work function metal layer comprises a TiN single-layered structure, a TiAl₃ single-layered structure, or a Ti/Al bi-layered structure.

24. The metal gates structure of claim 13, further comprising a top barrier layer and a low-resistance metal layer sequentially formed on the work function metal layer.
